(19) United States
(12) Patent Application Publication
(10) Pub. No.: US 2021/0134923 A1
(43) Pub. Date: May 6, 2021

(54) DISPLAY DEVICE

(71) Applicant: Samsung Display Co., LTD., Yongin-si (KR)

(72) Inventors: Jee Hoon KIM, Cheonan-si (KR); Shin Hyuk YANG, Seongnam-si (KR); Jong Moo HUH, Hwaseong-si (KR); Dong Han KANG, Hwaseong-si (KR); Min Chul SHIN, Seoul (KR); Jun Ki LEE, Hwaseong-si (KR); Jae Seol CHO, Seoul (KR)

(21) Appl. No.: 16/915,426

(22) Filed: Jun. 29, 2020

(30) Foreign Application Priority Data
Oct. 30, 2019 (KR) 10-2019-0136578

(51) Int. Cl. H01L 27/32; H01L 51/52

(52) U.S. Cl. CPC H01L 27/3276; H01L 2251/308; H01L 27/3258; H01L 51/5253

(57) ABSTRACT

A display device includes a substrate which includes a display area and a non-display area, a transistor disposed in the display area, a pad disposed in the non-display area, and an insulating layer which is disposed on the transistor and defines an opening which overlaps the pad in a plan view. The pad includes a main layer, a first auxiliary layer on the main layer, and a second auxiliary layer on the first auxiliary layer, and the second auxiliary layer defines the opening.

This application claims priority to Korean Patent Application No. 10-2019-0136578, filed on Oct. 30, 2019, and all the benefits accruing therefrom under 35 U.S.C. § 119, the content of which in its entirety is herein incorporated by reference.

### BACKGROUND

### (a) Technical Field

This disclosure relates to a display device.

### (b) Description of the Related Art

A display device, such as a light emitting display device and a liquid crystal display device, is used. The display device includes a display panel including pixels that display an image. In addition to the pixels, circuits, pads for inputting signals used to control the pixels and the circuits, and signal lines connected to the pads to transmit signals are formed in the display panel.

### SUMMARY

The pads include portions that are exposed without being covered by an insulating layer. Since the exposed portion may be damaged in a subsequent process, the top of the pads may be provided with a conductive layer that may prevent damage, and the conductive layer may be formed by further processing after forming a lower conductive layer.

According to embodiments, a display device has pads with improved reliability that may be formed without adding a mask.

A display device according to one or more embodiments includes a substrate which includes a display area and a non-display area, a transistor disposed in the display area, a pad disposed in the non-display area, and an insulating layer which is disposed on the transistor and defines an opening which overlaps the pad in a plan view. The pad includes a main layer, a first auxiliary layer on the main layer, and a second auxiliary layer on the first auxiliary layer, and the second auxiliary layer defines the opening.

The insulating layer may cover an edge of the pad, and the second auxiliary layer may be disposed between the first auxiliary layer and the insulating layer.

An edge of the second auxiliary layer and an edge of the first auxiliary layer may substantially coincide with each other.

The second auxiliary layer may include a conductive oxide.

The conductive oxide may include at least one of a zinc indium oxide, a gallium zinc oxide, and an aluminum zinc oxide.

The main layer may include copper, and the first auxiliary layer may include titanium.

The pad may further include a third auxiliary layer under the main layer.

The pad may be connected to a signal line disposed in the display area.

The display device may further include a pad connecting electrode which overlaps the pad, where the pad may be connected to the signal line through the pad connecting electrode.

The signal line may be a data line which transmits a data voltage, and the pad connecting electrode may be disposed in the same layer with the data line.

The display device may further include a connecting member disposed on a source or drain electrode of the transistor and connected to the source or drain electrode, where the pad may be disposed in the same layer with the connecting member.

The signal line may be a data line which transmits a data voltage, and the pad may be disposed in the same layer with the data line.

The pad and the data line may be monolithic.

The pad may be disposed in the same layer with the gate electrode of the transistor.

A display device according to one or more embodiments includes a substrate, a pad disposed on the substrate, and a first insulating layer which is disposed on the pad and defines an opening which overlaps a portion of the pad. The pad includes a main layer, a first auxiliary layer on the main layer, and a second auxiliary layer on the first auxiliary layer, and the first auxiliary layer is exposed in an area in which the second auxiliary layer defines the opening.

The first insulating layer may cover an edge of the pad, and the second auxiliary layer may be disposed between the first auxiliary layer and the first insulating layer.

Edges of the main layer, the first auxiliary layer, and the second auxiliary layer may substantially coincide with each other.

The main layer may include copper, the first auxiliary layer may include at least one of titanium, molybdenum, and tungsten, and the second auxiliary layer may include at least one of a zinc indium oxide, a gallium zinc oxide, and an aluminum zinc oxide.

The display device may further include a second insulating layer which is disposed on the first insulating layer and defines the opening, wherein the first insulating layer may include an inorganic insulating material, and the second insulating layer may include an organic insulating material.

The display device may further include a data line which is connected to the pad and transmits a data voltage, where the pad may be disposed in the same layer with the data line.

According to embodiments, it is possible to provide a display device having pads with improved reliability that may be formed without adding a mask. In addition, the display device according to the embodiments may provide an effect that may be recognized throughout the present specification.

### BRIEF DESCRIPTION OF THE DRAWINGS

FIG. 1 schematically illustrates a top plan view of a display device according to an embodiment.

FIG. 2 illustrates a schematic cross-sectional view of an embodiment taken along line A-A′ of FIG. 1.

FIG. 3 illustrates an enlarged view of area B of FIG. 2.

FIG. 4, FIG. 5, FIG. 6, and FIG. 7 are cross-sectional views illustrating a manufacturing method of a display device according to an embodiment.

FIG. 8 illustrates a schematic cross-sectional view of an embodiment taken along line A-A′ of FIG. 1.

FIG. 9 illustrates a schematic cross-sectional view of a display device according to an embodiment.

FIG. 10 illustrates an enlarged view of area C of FIG. 9.

FIG. 11, FIG. 12, and FIG. 13 are cross-sectional views illustrating a manufacturing method of a display device according to an embodiment.

FIG. 14 illustrates a schematic cross-sectional view of a display device according to an embodiment.

FIG. 15 illustrates a schematic cross-sectional view of a display device according to an embodiment.

FIG. 16 illustrates an equivalent circuit diagram of one pixel of a display according to an embodiment.

### DETAILED DESCRIPTION

The inventive concept will be described more fully hereinafter with reference to the accompanying drawings, in which embodiments are shown. As those skilled in the art would realize, the described embodiments may be modified in various different ways, all without departing from the spirit or scope of the present disclosure.

Parts that are irrelevant to the description will be omitted to clearly describe the present disclosure, and like reference numerals designate like elements throughout the specification.

Further, in the drawings, the size and thickness of each element are arbitrarily illustrated for ease of description, but the present disclosure is not limited to those illustrated in the drawings. In the drawings, the thicknesses of layers, films, panels, areas, regions, etc., are exaggerated for clarity. In the drawings, for ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

In the specification, unless explicitly described to the contrary, the word “comprise” and variations such as “comprises” or “comprising” will be understood to imply the inclusion of stated elements but not the exclusion of any other elements.

In the drawings, as symbols used for indicating directions, “x” is a first direction, “y” is a second direction perpendicular to the first direction, and “z” is a third direction perpendicular to the first direction and the second direction. The first direction x, the second direction y, and the third direction z may correspond to a horizontal direction, a vertical direction, and a thickness direction of the display device, respectively.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In the present specification, unless otherwise noted, “being overlapped” means being overlapped when viewed in a plan view, and being overlapped in the third direction z.

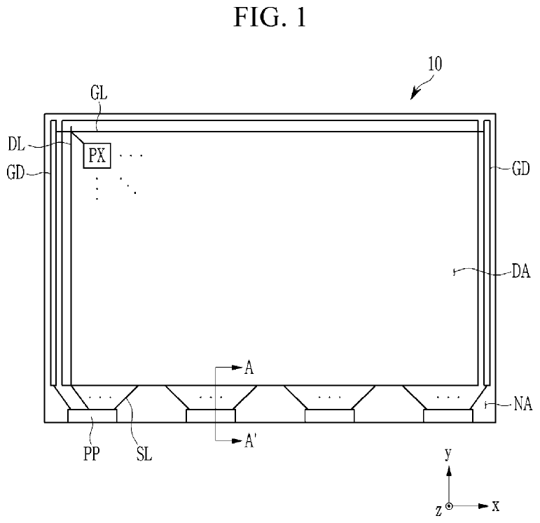

FIG. 1 schematically illustrates a top plan view of a display device according to an embodiment.

Referring to FIG. 1, the display device includes a display panel 10. The display panel 10 includes a display area DA for displaying an image, and a non-display area NA in which circuits and/or signal lines for generating and/or transmitting various signals applied to the display area DA are disposed, and the non-display area NA is around the display area DA.

In the display area DA of the display panel 10, pixels PX are arranged in a matrix, for example. Signal lines such as data lines DL and gate lines GL are disposed in the display area DA. The gate lines GL may substantially extend in a first direction x (for example, a row direction in FIG. 1), and the data lines DL may substantially extend in a second direction y (for example, a column direction in FIG. 1). The gate line GL and the data line DL may be connected to each pixel PX, and each pixel PX may receive a gate signal and a data voltage from the signal lines. In a case of a light emitting display device, driving voltage lines (not shown) for transmitting a driving voltage to the pixels PX may be disposed in the display area DA. In addition, sensing signal lines for transmitting a sensing signal, light emitting control lines for transmitting a light emitting control signal, and/or initializing voltage lines for transmitting an initializing voltage may be further disposed in the display area DA.

In the display area DA, a touch sensor layer for detecting a user's contact or non-contact touch may be disposed.

In the non-display area NA of the display panel 10, a pad portion PP in which pads corresponding to input connecting terminals for receiving signals from the outside of the display panel 10 are arranged is disposed. According to a size of the display panel 10, a plurality of pad portions PP that are spaced apart from each other may be included. An electronic component such as a flexible printed circuit film may be bonded to the pad portion PP, and pads and/or bumps of the electronic component may be electrically connected to pads of the pad portion PP.

A driving unit for generating and/or processing various signals for driving the display panel 10 is included in the non-display area NA of the display panel 10 of the display device. The driving device may include a data driver (not shown) for applying a data voltage to the data lines DL, a gate driver GD for applying a gate signal to the gate lines GL, and a signal controller (not shown) for controlling the data driver and the gate driver GD.

The gate driver GD may be disposed in the display panel 10, and may be integrated in the non-display area NA disposed at least one side of the display area DA. The gate driver GD may be provided as a type of an integrated circuit chip. The data driver may be provided as a type of an integrated circuit chip, and it may be disposed in a flexible printed circuit film bonded to the pad portion PP or the non-display area NA of the display panel 10. The signal controller may be provided as a type of an integrated circuit chip, and it may be disposed on a printed circuit board to which a flexible printed circuit film is bonded. The data driver and the signal controller may both be provided as a type of an integrated chip.

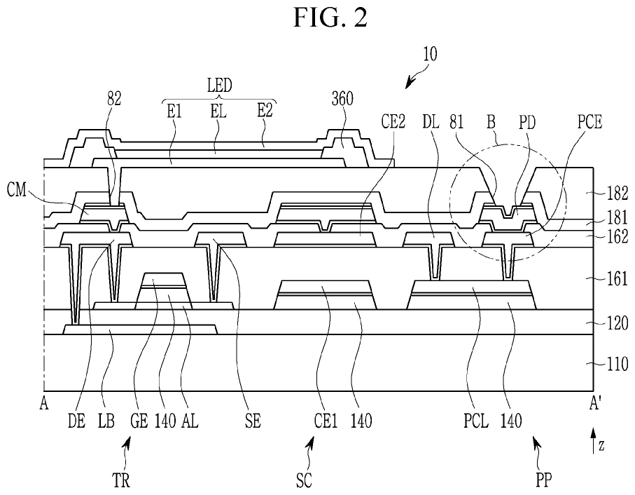

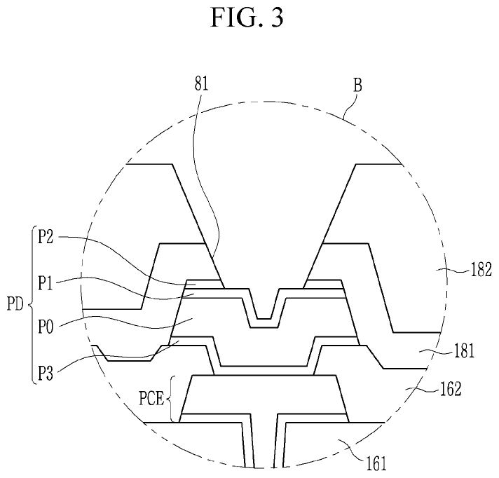

FIG. 2 illustrates a schematic cross-sectional view of an embodiment taken along line A-A′ of FIG. 1, and FIG. 3 illustrates an enlarged view of area B of FIG. 2.

Referring to FIG. 2 and FIG. 3, a cross-sectional structure of the display panel 10 will be described in detail.

The display panel 10 includes a substrate 110, and layers, wires, and elements formed thereon. Although a large number of pixels are disposed in the display area DA of the display panel 10, only one pixel PX is briefly illustrated and described in order to avoid complexity of the drawing. In addition, each pixel PX of the display area DA may include a plurality of transistors, one or more capacitors, and a light emitting diode. However, here, one transistor TR, one storage capacitor SC, and one light emitting diode LED will be illustrated and described as an example.

The substrate 110 may be a rigid substrate made of glass, quartz, ceramic, or the like. The substrate 110 may be a flexible substrate made of a polymer such as polyimide or polyamide.

A light blocking layer LB may be disposed on the substrate 110. The light blocking layer LB may prevent external light from reaching a semiconductor layer AL of the transistor TR, thereby preventing deterioration of characteristics of the semiconductor layer AL. The light blocking layer LB may control a leakage current of the transistor TR, particularly a driving transistor of which current characteristics are important in the light emitting display device. The light blocking layer LB may include a material that does not transmit light of a wavelength band to be blocked, and may be a metal layer. The light blocking layer LB may function as an electrode to which a specific voltage is applied in the display panel 10. In this case, a change rate of a current in a saturation region of a voltage-current characteristic graph of the transistor TR decreases, such that the characteristics of the transistor may be improved.

A buffer layer 120 may be disposed on the light blocking layer LB. In a process of forming the semiconductor layer AL, the buffer layer 120 may block impurities that may diffuse from the substrate 110 to the semiconductor layer AL and reduce stress applied to the substrate 110. The buffer layer 120 is an insulating layer that may include an inorganic insulating material such as a silicon oxide and a silicon nitride.

The semiconductor layer AL of the transistor TR may be disposed on the buffer layer 120. The semiconductor layer AL may include a channel region overlapping a gate electrode GE, and doped source and drain regions at respective sides thereof. The semiconductor layer AL may include a semiconductor material such as an oxide semiconductor, a polycrystalline silicon, and an amorphous silicon.

A gate insulating layer 140 including an inorganic insulating material such as a silicon oxide and a silicon nitride may be disposed on the semiconductor layer AL.

A gate conductor including a gate line GL, the gate electrode GE of the transistor TR, a first electrode CE1 of the storage capacitor SC, and a pad connecting line PCL may be disposed on the gate insulating layer 140. The pad connecting line PCL is a line connecting the pad PD of the pad portion PP to a signal line such as a data line DL, and the pad connecting line PCL may be disposed between the display area DA and the pad portion PP. The pad connecting line PCL may be an extension of the signal line. The first electrode CE1 may be connected to the gate electrode GE. The gate conductor may include metals such as copper (Cu), molybdenum (Mo), aluminum (Al), silver (Ag), chromium (Cr), tantalum (Ta), and titanium (Ti). The gate conductor may be a multilayer. For example, the gate conductor may be a double layer that includes a lower auxiliary layer including molybdenum (Mo) and/ or titanium (Ti) and an upper main layer including a low resistivity metal such as copper (Cu). In the structure shown in the figures, the gate conductor is a double layer including a thin auxiliary layer and a thick main layer.

A first interlayer insulating layer 161 may be disposed on the gate insulating layer 140 and the gate conductor. The first interlayer insulating layer 161 may include an inorganic insulating material such as a silicon oxide and a silicon nitride.

A first data conductor including a source electrode SE and a drain electrode DE of the transistor TR, a data line DL, a second electrode CE2 of the storage capacitor SC, and a pad connecting electrode PCE may be disposed on the first interlayer insulating layer 161. The source electrode SE and the drain electrode DE may be connected to a source region and a drain region of the semiconductor layer AL through openings defined in the first interlayer insulating layer 161, respectively. One of the source electrode SE and the drain electrode DE may be connected to the light blocking layer LB through the openings defined in the first interlayer insulating layer 161 and the buffer layer 120. The data line DL and the pad connecting electrode PCE may be connected to the pad connecting line PCL through the opening defined in the first interlayer insulating layer 161. Accordingly, the data line DL and the pad connecting electrode PCE may be electrically connected by the pad connecting line PCL. The second electrode CE2 may be connected to the drain electrode DE.

The first data conductor may include metals such as copper (Cu), aluminum (Al), silver (Ag), titanium (Ti), molybdenum (Mo), tungsten (W), chromium (Cr), and tantalum (Ta). The first data conductor may be a multilayer, for example, a double layer such as a titanium/copper (Ti/Cu) or titanium/aluminum (Ti/Al). The relatively thick main layer of the multi-layered first data conductor may include a low resistivity metal, and the lower and/or upper auxiliary layers of the multi-layered first data conductor may include metals that may improve contact characteristics with other layers. In the illustrated embodiment shown in FIGS. 2 and 3, the pad connecting electrode PCE includes the main layer and the auxiliary layer thereunder.

The gate electrode GE, the source electrode SE, and the drain electrode SE form a transistor TR together with the semiconductor layer AL. A structure of the transistor TR may be variously changed.

A second interlayer insulating layer 162 may be disposed on the first interlayer insulating layer 161 and the first data conductor. The second interlayer insulating layer 162 may include an inorganic insulating material such as a silicon oxide and a silicon nitride.

A second data conductor including a connecting member CM and a pad PD may be disposed on the second interlayer insulating layer 162. The second data conductor may further include a power line such as a driving voltage line, a common voltage line, and/or an initializing voltage line. The connecting member CM may be connected to the drain electrode DE through an opening defined in the second interlayer insulating layer 162. The pad PD may overlap the pad connecting electrode PCE in a plan view, and the pad PD may be connected to the pad connecting electrode PCE through an opening defined in the second interlayer insulating layer 162. Since the pad connecting electrode PCE is electrically connected to a signal line such as the data line DL, the pad PD may be electrically connected to the signal line. The pad PD is a portion that is electrically connected to a pad such as a flexible printed circuit film through an anisotropic conductive film, solder, or the like. At least a portion of an upper surface of the pad PD may be exposed to the outside before an electronic component such as a flexible printed circuit film is connected thereto.

The second data conductor may include metals such as copper (Cu), aluminum (Al), silver (Ag), titanium (Ti), molybdenum (Mo), tungsten (W), chromium (Cr), and tantalum (Ta). The second data conductor may be a multilayer including at least three layers. The multilayer may be formed by successively stacking layers while the layers have varying materials. The second data conductor may include a main layer including a low resistivity metal, a first auxiliary layer and a second auxiliary layer sequentially disposed at an upper portion of the main layer. The second data conductor may further include a third auxiliary layer disposed at a lower portion of the main layer. The third auxiliary layer, the main layer, the first auxiliary layer, and the second auxiliary layer may have substantially coincident edges.

As an example of the multi-layered structure of the second data conductor, the pad PD includes a third auxiliary layer P3, a main layer P0, a first auxiliary layer P1, and a second auxiliary layer P2 that are sequentially stacked in this order.

The third auxiliary layer P3 disposed at the bottom of the pad PD is in contact with the pad connecting electrode PCE, and may include a metal such as titanium (Ti), molybdenum (Mo), or the like. The main layer P0 may include a low resistivity metal such as copper (Cu), aluminum (Al), and silver (Ag).

After the formation of the second data conductor in the manufacturing of the display panel 10, the first auxiliary layer P1 may prevent the main layer P0 from being damaged in a subsequent process (for example, an etching process for forming a first electrode E1 of the light emitting diode LED). The first auxiliary layer P1 may include a corrosion resistant material such as titanium (Ti), molybdenum (Mo), and tungsten (W).

A surface of the first auxiliary layer P1 may be oxidized, and an oxide such as a titanium oxide (TiOₓ) may be formed on the surface of the first auxiliary layer P1 as a result of the oxidization. Since such an oxide forms a film (i.e., oxide film), when the oxide film is thickly or non-uniformly formed, it is difficult to control an etching process for forming the second data conductor, and the uniformity of the second data conductor may be degraded. In addition, the pads PD of the pad portion PP may be non-uniformly formed and the characteristics thereof may be degraded.

According to an embodiment, the second auxiliary layer P2 is disposed on the first auxiliary layer P1, thereby suppressing occurrence of the oxide film of the first auxiliary layer P1. Accordingly, it is possible to reduce a thickness and a dispersion of the oxide film of the first auxiliary layer P1, the etching process control for forming the second data conductor is easy, and it is possible to improve structural uniformity associated with taper, skew, upper tip, and the like of the second data conductor (particularly, the pad PD).

The second auxiliary layer P2 may include or be formed of a material that is etchable by an etchant that does not etch or damage the first auxiliary layer P1. For example, the second auxiliary layer P2 may include a conductive oxide such as a zinc indium oxide (“ZIO”), a gallium zinc oxide (“GZO”), and an aluminum zinc oxide (“AZO”). In the zinc indium oxide (ZIO), a ratio of zinc (Zn): indium (In) may be about 9:1 to about 1:9. In the gallium zinc oxide (GZO), a ratio of zinc may be about 10% to about 90%. The second auxiliary layer P2 may include an insulating material.

A passivation layer 181 may be disposed on the second interlayer insulating layer 162 and the second data conductor. The passivation layer 181 is an insulating layer that may include an inorganic insulating material such as a silicon oxide and a silicon nitride. The passivation layer 181 may include an organic insulating material.

The passivation layer 181 defines an opening 81 overlapping the pad PD in a plan view such that the pad PD may be exposed to the outside for connection with a pad or the like of the flexible printed circuit film. The opening 81 is defined such that an upper surface of the pad PD is not completely exposed, and the passivation layer 181 covers an edge of the pad PD. The second auxiliary layer P2 of the pad PD may overlap the passivation layer 181 and may define the opening 81. An edge of the second auxiliary layer P2 may substantially coincide with an edge of the first auxiliary layer P1. A portion of the pad PD overlapping the opening 81 may be an upper surface of the first auxiliary layer P1.

An insulating layer 182 including an organic insulating material such as a polyimide, an acrylic polymer, or a siloxane polymer may be disposed on the passivation layer 181. The pad PD may be exposed through the opening 81 defined in the insulating layer 182 and the passivation layer 181.

A first electrode E1 of the light emitting diode LED may be disposed on the insulating layer 182. The first electrode E1 may be connected to the connecting member CM through an opening 82 defined in the passivation layer 181 and the insulating layer 182. A portion overlapping the opening 82 in the second auxiliary layer (i.e., the upper layer of the connecting member CM) of the connecting member CM, which is the second data conductor, may be eliminated. The first electrode E1 may be electrically connected to the drain electrode DE of the transistor TR through the connecting member CM. The first electrode E1 of the light emitting diode LED includes metals such as silver (Ag), nickel (Ni), gold (Au), platinum (Pt), aluminum (Al), copper (Cu), neodymium (Nd), and lanthanum (La). The first electrode E1 may include a transparent conductive oxide such as an indium tin oxide (“ITO”) and an indium zinc oxide (“IZO”). The first electrode E1 may be a multilayer such as ITO/silver (Ag)/ITO and ITO/aluminum (Al).

A partition wall 360 having an opening overlapping the first electrode E1 may be disposed on the insulating layer 182. An opening defined in the partition wall 360 may define each pixel area, and may be referred to as a pixel defining layer. The partition wall 360 is an insulating layer that may include an organic insulating material such as polyimide or polyacrylic.

A light emitting layer EL is disposed on the first electrode E1, and a second electrode E2 is disposed on the light emitting layer EL. The second electrode E2 may have a light transmittance by forming a thin layer of a metal or a metal alloy having a low work function such as calcium (Ca), barium (Ba), magnesium (Mg), aluminum (Al), silver (Ag), or the like. The second electrode E2 may include a transparent conductive oxide such as an ITO and an IZO.

The first electrode E1, the light emitting layer EL, and the second electrode E2 of each pixel PX form the light emitting diode LED such as an organic light emitting diode. The first electrode E1 may be an anode and the second electrode E2 may be a cathode.

An encapsulating layer (not shown) may be disposed on the second electrode E2 to seal the light emitting diode LED and the like to prevent moisture or oxygen from penetrating from the outside. The encapsulating layer may be a thin film encapsulating layer formed by evaporation or the like, or a substrate bonded by a sealant, and may be disposed not to cover the pad PD.

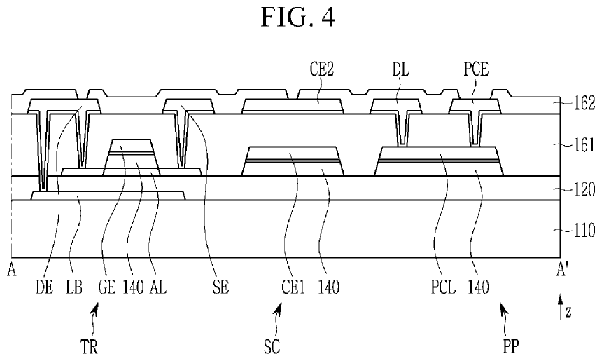

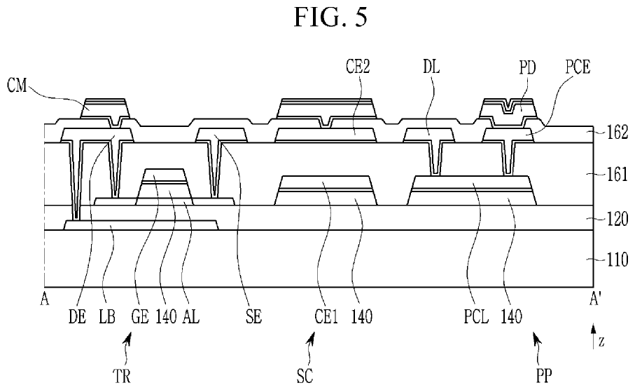

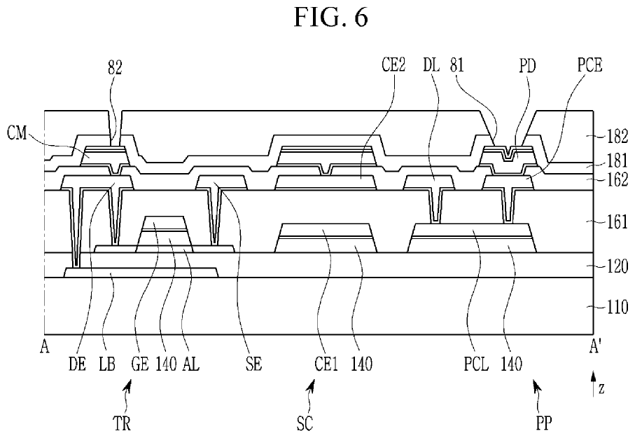

A method of manufacturing a display panel having a cross-sectional structure as shown in FIG. 2 will be described with reference to FIG. 4 to FIG. 7.

FIG. 4, FIG. 5, FIG. 6, and FIG. 7 are cross-sectional views illustrating a manufacturing method of a display device according to an embodiment.

Referring to FIG. 4, a conductive layer is formed on the substrate 110 through sputtering or the like, and the light blocking layer LB is formed by patterning the conductive layer by a photolithography process. Hereinafter, patterning by a photolithography process using a photoresist and a mask is simply referred to as patterning.

The buffer layer 120 is formed of an inorganic insulating material on the substrate 110 on which the light blocking layer LB is formed through chemical vapor deposition and the like. The semiconductor layer AL is formed by forming and patterning a semiconductor material layer on the buffer layer 120 through chemical vapor deposition. The gate insulating layer 140 is formed of an inorganic insulating material on the substrate 110 (more specifically, on the buffer layer 120) on which the semiconductor layer AL is formed. In this step, the gate insulating layer 140 is formed over the entire surface of the substrate 110 (more specifically, over the entire surface of the buffer layer 120).

The conductive layer is formed and patterned on the gate insulating layer 140 by sputtering or the like to form a gate conductor including the gate electrode GE, the first electrode CE1, and the pad connecting line PCL. In this step, the gate insulating layer 140 may be etched, and then the gate insulating layer 140 may remain disposed only in an area overlapping the gate conductor. Since a portion of the gate insulating layer 140 that does not overlap the gate electrode GE is eliminated, the source region and the drain region may be exposed in the semiconductor layer AL after the etching.

The first interlayer insulating layer 161 is formed of an inorganic insulating material and patterned on the substrate 110 (more specifically, on the buffer layer 120) on which the gate conductor is formed, and openings overlapping the source and drain regions of the semiconductor layer AL and the pad connecting line PCL are defined in the first interlayer insulating layer 161. In this step, an opening overlapping the light blocking layer LB may be defined in the first interlayer insulating layer 161 and the buffer layer 120.

A conductive layer is formed and patterned on the first interlayer insulating layer 161 to form the first data conductor including the source electrode SE and the drain electrode DE of the transistor TR, the data line DL, the second electrode CE2 of the storage capacitor SC, and the pad connecting electrode PCE. The source electrode SE, the drain electrode DE, the data line DL, and the pad connecting electrode PCE may be connected to the source region, the drain region, and the pad connecting line PCL through the openings defined in the first interlayer insulating layer 161 as shown in FIG. 4. The drain electrode DE may also be connected to the light blocking layer LB through the opening defined in the first interlayer insulating layer 161 and the buffer layer 120. For example, the first data conductor may include or be formed by sequentially stacking an auxiliary layer including titanium (Ti) and a main layer including copper (Cu), and then patterning both the main layer and the auxiliary layer at once.

The second interlayer insulating layer 162 is formed of an inorganic insulating material and patterned on the substrate 110 (more specifically, on the first interlayer insulating layer 161) on which the first data conductor is formed, and the second interlayer insulating layer 162 may define openings overlapping the drain electrode DE and the pad connecting electrode PCE.

Referring to FIG. 5, a conductive layer is formed and patterned on the second interlayer insulating layer 162 to form the second conductor including the connecting member CM and the pad PD. The connecting member CM and the pad PD may be connected to the drain electrode DE and the pad connecting electrode PCE, respectively, through the openings defined in the second interlayer insulating layer 162. The second data conductor may be formed by sequentially stacking four layers and then patterning them at once. For example, the second conductor may be formed by successively stacking and patterning a first layer containing titanium (Ti), a second layer containing copper (Cu), a third layer containing titanium (Ti), and a fourth layer which is a conductive oxide layer. In an embodiment, the second layer may correspond to the main layer, the third layer and the fourth layer may correspond to the first auxiliary layer and the second auxiliary layer, and the first layer may correspond to the third auxiliary layer.

Since the second auxiliary layer is continuously formed on the first auxiliary layer and then patterned to form a second data conductor together, the formation of the oxide film in the first auxiliary layer may be suppressed, and even if the oxide film is formed on the first auxiliary layer, its thickness and dispersion may be reduced. Therefore, it is easy to control the etching process for forming the second data conductor, and it is possible to improve structural uniformity associated with taper, skew, upper tip, and the like of the second data conductor, and the reliability of the display device may be improved. In this step, the second data conductor disposed in the uppermost layer may have a different structure from that of the second data conductor in the display panel 10 finally manufactured. That is, the second auxiliary layer P2 of the pad PD completely covers an upper surface of the first auxiliary layer P1 in this step.

Referring to FIG. 6, the passivation layer 181 is formed of an inorganic insulating material on the substrate 110 (more specifically, on the second interlayer insulating layer 162) on which the second data conductor is formed, and the insulating layer 182 is formed of an organic insulating material on the passivation layer 181. Then, the insulating layer 182 and the passivation layer 181 are patterned to define the opening 81 overlapping the pad PD and the opening 82 overlapping the connecting member CM. A center portion of the second auxiliary layer P2, which is the uppermost layer of the pad PD, is exposed by the opening 81, and an edge of the second auxiliary layer P2 is covered by the passivation layer 181. Since an edge of the pad PD is capped by the passivation layer 181, the edge of the pad PD may be prevented from being lifted up or corroded.

Referring to FIG. 7, the center portion of the second auxiliary layer P2 of the pad PD exposed through the opening 81 is wet-etched with an etchant. In this stage, a portion of the second auxiliary layer of the connecting member CM exposed through the opening 82 may also be etched. An etchant having high selectivity to a material of the first auxiliary layer P1 may be used such that the first auxiliary layer P1 is not etched when the second auxiliary layer P2 is etched. Since the portion of the second auxiliary layer P2 which is exposed by the opening 81 is etched, the first auxiliary layer P1 of the pad PD is exposed in the region overlapping the opening 81. However, since the portion of the second auxiliary layer P2 that is not exposed by the opening 81 is not etched, the portion of the second auxiliary layer P2 overlapping the passivation layer 181 remains between the first auxiliary layer P1 and the passivation layer 181.

An etchant having high selectivity to a material of the first auxiliary layer P1 which is an exposed layer of the pad PD may be used such that the pad PD is not damaged when the conductive layer for forming the first electrode E1 is etched. For example, in a case that the main layer P0 of the pad PD is formed of copper (Cu) and the first electrode E1 is formed of an ITO, the main layer P0 may be eroded by the etchant used during patterning for forming the first electrode E1 if the first auxiliary layer P1 does not cover the main layer P0. However, in an embodiment, since the first auxiliary layer P1 formed of a metal having excellent corrosion resistance to the etchant of ITO, such as titanium (Ti), covers the main layer P0, it is possible to prevent the pad PD from being damaged. In addition, since the first auxiliary layer P1 is formed together using the same mask in the process of forming the main layer P0, an additional mask is not required in forming the auxiliary layer for protecting the main layer P0 from an etchant used in a subsequent process.

Referring back to FIG. 2, a conductive layer is formed and patterned on the insulating layer 182 to form the first electrode E1 of the light emitting diode LED. The first electrode E1 is connected to the connecting member CM through the opening 82 defined in the insulating layer 182. Since the portion of the second auxiliary layer of the connecting member CM overlapping the opening 82 is eliminated, the first electrode E1 may contact an upper surface of the first auxiliary layer of the connecting member CM. The first electrode E1 may be connected to the drain electrode DE through the connecting member CM.

Next, an organic insulating material is formed and patterned on the substrate 110 (more specifically, on the insulating layer 182) on which the first electrode E1 is formed to form the partition wall 360 defining the opening overlapping the first electrode E1. Subsequently, the light emitting layer EL overlapping the first electrode E1 is formed and the second electrode E2 covering both the light emitting layer EL and the partition wall 360 is formed, such that the display panel 10 having the cross-sectional structure as illustrated in FIG. 2 may be manufactured.

In an embodiment, the portion overlapping the opening 81 in the second auxiliary layer P2 of the pad PD may be eliminated together during patterning for forming the first electrode E1. Since the pad PD is exposed due to the opening 81 during patterning for forming the first electrode E1 of the light emitting diode LED, the second auxiliary layer P2 may be etched together by using an etchant that can etch both the second auxiliary layer P2 and the first electrode E1. In this case, the portion of the second auxiliary layer of the connecting member CM that overlaps the opening 82 is not eliminated and completely covers the first auxiliary layer. As another example, the second auxiliary layer P2 may be entirely eliminated after forming the second data conductor and before forming the passivation layer 181.

Hereinafter, some additional embodiments will be described focusing on differences from the above embodiments.

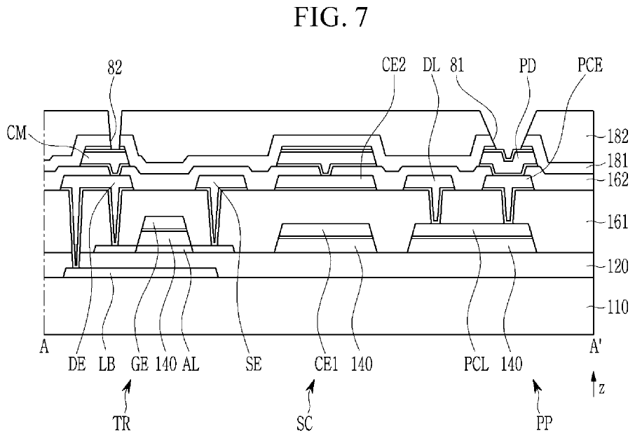

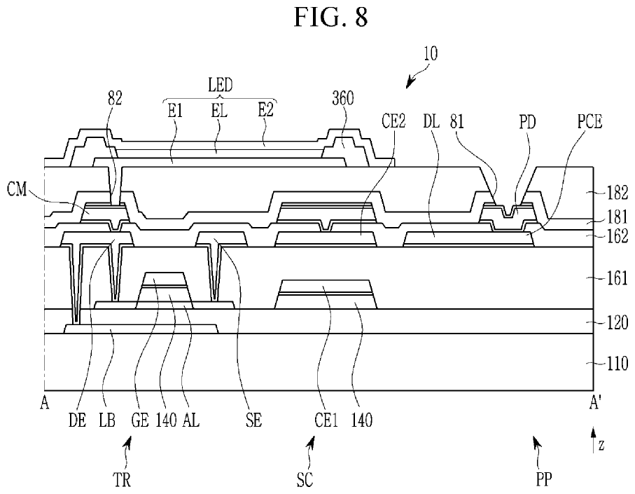

FIG. 8 illustrates a schematic cross-sectional view of an embodiment taken along line A-A′ of FIG. 1.

The embodiment of FIG. 8 differs from the embodiment of FIG. 2 in the connection of the data line DL and the pad PD. In the embodiment of FIG. 2, the data line DL and the pad connecting electrode PCE are electrically connected to each other through the pad connecting line PCL, which is a gate conductor. The display panel 10 of the embodiment of FIG. 8 does not include the pad connecting line PCL, and the data line DL extends to the pad PD such that the data line DL and the pad connecting electrode PCE are integrally formed (i.e., monolithic). Accordingly, the pad connecting electrode PCE may be regarded as an extension portion or an expansion portion of the data line DL.

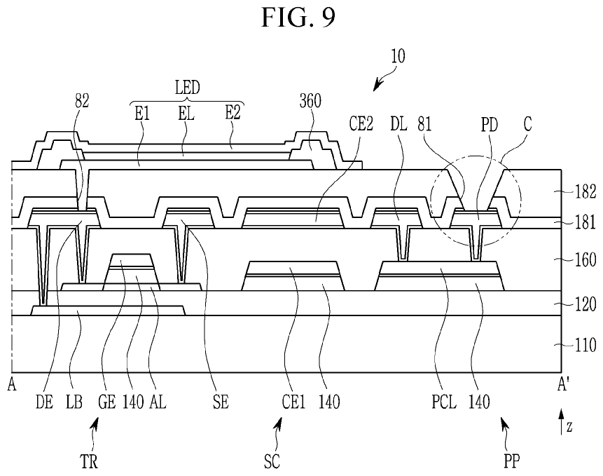

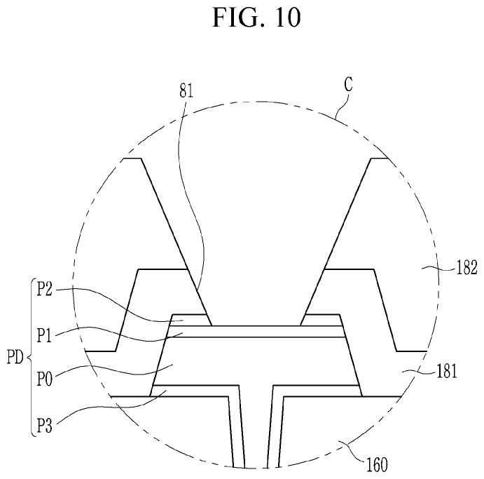

FIG. 9 illustrates a schematic cross-sectional view of a display device according to an embodiment, and FIG. 10 illustrates an enlarged view of portion C of FIG. 9. FIG. 9 may correspond to a cross-section along line A-A′ of FIG. 1.

Referring to FIG. 9 and FIG. 10, unlike the embodiment of FIG. 2, the display panel 10 does not include the second data conductor. Accordingly, the display panel 10 does not include the second interlayer insulating layer for insulating the first data conductor and the second data conductor. In the embodiment of FIG. 2, the element referred to as the first data conductor is referred to as a data conductor, and the insulating layer referred to as the first interlayer insulating layer is referred to as an interlayer insulating layer 160.

Similar to the embodiment of FIG. 2, in the display panel 10 of the embodiment of FIG. 9, the light blocking layer LB is disposed on the substrate 110, and the buffer layer 120 covering the light blocking layer LB is disposed on the substrate 110. The semiconductor layer AL and the gate insulating layer 140 of the transistor TR are disposed on the buffer layer 120. A gate conductor including the gate electrode GE of the transistor TR, the first electrode CE1 of the storage capacitor SC, and the pad connecting line PCL is disposed on the gate insulating layer 140, and the interlayer insulating layer 160 covering the gate conductor is disposed thereon.

A data conductor including the source electrode SE and the drain electrode DE of the transistor TR, the data line DL, the second electrode CE2 of the storage capacitor SC, and the pad PD is disposed on the interlayer insulating layer 160. The source electrode SE and the drain electrode DE may be connected to the source region and the drain region of the semiconductor layer Al through the openings defined in the interlayer insulating layer 160, respectively. One of the source electrode SE and the drain electrode DE may be connected to the light blocking layer LB through the openings defined in the interlayer insulating layer 160 and the buffer layer 120. The data line DL and the pad PD may be connected to the pad connecting line PCL through the opening defined in the interlayer insulating layer 160. Accordingly, the data line DL and the pad PD may be electrically connected by the pad connecting line PCL. The data conductor may further include a power line such as a driving voltage line, a common voltage line, and/or an initializing voltage line.

Similar to the second data conductor of the embodiment of FIG. 2, the data conductor may be a multilayer including at least three layers. The multilayer may be formed by successively stacking layers while the layers have varying materials. The data conductor may include a main layer including a low resistivity metal, a first auxiliary layer, and a second auxiliary layer sequentially disposed at an upper portion of the main layer. The data conductor may further include a third auxiliary layer disposed at a lower portion of the main layer.

The pad PD is a portion that is electrically connected to a connecting terminal such as a pad or a bump of an electronic component such as a flexible printed circuit film through an anisotropic conductive film, solder, or the like. As an example of the multi-layered structure of the data conductor, the pad PD includes a third auxiliary layer P3, a main layer P0, a first auxiliary layer P1, and a second auxiliary layer P2 that are sequentially stacked in this order.

The third auxiliary layer P3 disposed at the bottom may include a metal such as titanium (Ti) and molybdenum (Mo). The main layer P0 may include a low resistivity metal such as copper (Cu), aluminum (Al), and silver (Ag). After the formation of the data conductor in the manufacturing of the display panel 10, the first auxiliary layer P1 may prevent the main layer P0 from being damaged in a subsequent process (for example, an etching process for forming a first electrode E1 of the light emitting diode LED). The first auxiliary layer P1 may include a corrosion resistant material such as titanium (Ti), molybdenum (Mo), and tungsten (W).

A surface of the first auxiliary layer P1 may be oxidized, and an oxide such as a titanium oxide (TiOx) may be formed on the surface of the first auxiliary layer P1 as a result of the oxidization. Since such an oxide forms an oxide film, when the oxide film is thickly or non-uniformly formed, it is difficult to control an etching process for forming the data conductor, and the uniformity of the data conductor may be degraded. In addition, the second auxiliary layer P2 is disposed on the first auxiliary layer P1, thereby suppressing occurrence of an oxide film of the first auxiliary layer P1. Accordingly, it is possible to reduce the thickness and dispersion of the oxide film of the first auxiliary layer P1, to easily control the etching process for forming the data conductor, and to improve the structural uniformity of the data conductor (particularly, the pad PD). The second auxiliary layer P2 may include a conductive oxide such as a zinc indium oxide (ZIO), a gallium zinc oxide (GZO), and an aluminum zinc oxide (AZO). The second auxiliary layer P2 may include an insulating material.

The passivation layer 181 is disposed on the interlayer insulating layer 160 and the data conductor, and the insulating layer 182 is disposed on the passivation layer 181. The insulating layer 182 and the passivation layer 181 define the opening 81 overlapping the pad PD such that the pad PD may be exposed to the outside. The opening 81 may be defined such that the pad PD may not be completely exposed. That is, the passivation layer 181 may cover the edge of the pad PD. The entire portion of the second auxiliary layer P2 of the pad PD may overlap the passivation layer 181.

The first electrode E1 of the light emitting diode LED is disposed on the insulating layer 182, and the first electrode E1 is connected to the drain electrode DE through the opening 82 defined in the insulating layer 182 and the passivation layer 181. A portion overlapping the opening 82 in the second auxiliary layer of the drain electrode DE, which is a data conductor, may be eliminated.

The partition wall 360 defining an opening overlapping the first electrode E1 is disposed on the insulating layer 182, the light emitting layer EL is disposed on the first electrode E1, and the second electrode E2 is disposed on the light emitting layer EL. The first electrode E1, the light emitting layer EL, and the second electrode E2 of each pixel PX form the light emitting diode LED such as an organic light emitting diode.

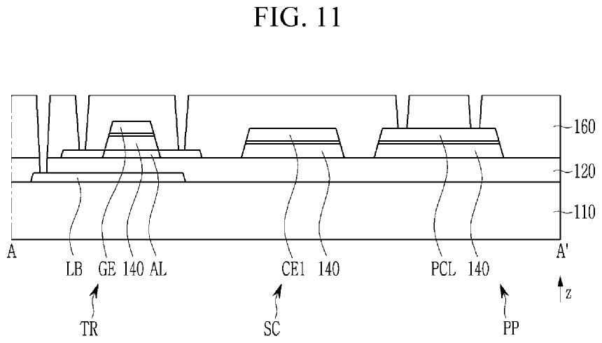

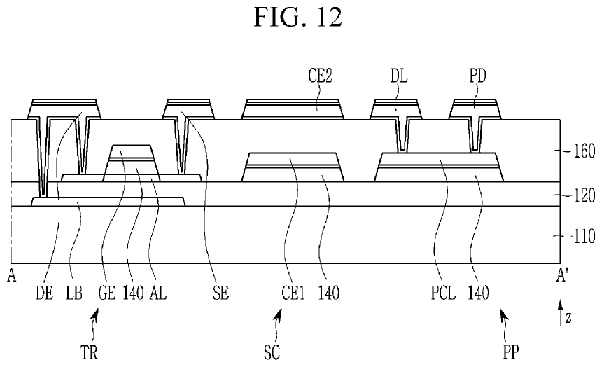

A method of manufacturing a display panel having the cross-sectional structure as shown in FIG. 9 will be described with reference to FIG. 11 to FIG. 13.

Referring to FIG. 11, steps of forming the light blocking layer LB, the buffer layer 120, the semiconductor layer AL, the gate insulating layer 140, and the gate conductors GE, CE1, and PCL on the substrate 110 may be the same as the steps described with reference to FIG. 4. Then, the interlayer insulating layer 160 is formed and patterned of an inorganic insulating material on the substrate 110 (more specifically on the buffer layer 120) on which the gate conductor is formed and the openings overlapping the source region and the drain region of the semiconductor layer AL and the pad connecting line PCL are defined in the interlayer insulating layer 160, and the opening overlapping the light blocking layer LB is formed in the interlayer insulating layer 160 and the buffer layer 120.

Referring to FIG. 12, a conductive layer is formed and patterned on the interlayer insulating layer 160 to form a data conductor including the source electrode SE and the drain electrode DE of the transistor TR, the data line DL, the second electrode CE2 of the storage capacitor SC, and the pad PD. The source electrode SE, the drain electrode DE, the data line DL, and the pad PD may be connected to the source region, the drain region, and the pad connecting line PCL through the openings defined in the interlayer insulating layer 160. The drain electrode DE may also be connected to the light blocking layer LB through the opening defined in the interlayer insulating layer 160 and the buffer layer 120. The data conductor may be formed by successively stacking four layers and then patterning them at once. For example, the data conductor may be formed by successively stacking and patterning a first layer containing titanium (Ti), a second layer containing copper (Cu), a third layer containing titanium (Ti), and a fourth layer which is a conductive oxide layer. In an embodiment, the second layer may correspond to the main layer, the third layer and the fourth layer may correspond to the first auxiliary layer and the second auxiliary layer, respectively, and the first layer may correspond to the third auxiliary layer.

Since the second auxiliary layer is continuously formed on the first auxiliary layer and then patterned to form a data conductor together, the formation of the oxide film in the first auxiliary layer may be suppressed, and even if the oxide film is formed on the first auxiliary layer, its thickness and dispersion may be reduced. Therefore, it is easy to control the etching process for forming the data conductor, and it is possible to improve the structural uniformity of the data conductor. In this step, the data conductor disposed in the uppermost layer may have a different structure from that of the data conductor in the display panel 10 finally manufactured. For example, the second auxiliary layer P2 of the pad PD completely covers an upper surface of the first auxiliary layer P1 in this step.

Referring to FIG. 13, the passivation layer 181 is formed of an inorganic insulating material on the substrate 110 (more specifically, on the interlayer insulating layer 160) on which the data conductor is formed, and the insulating layer 182 is formed of an organic insulating material on the passivation layer 181. Then, the insulating layer 182 and the passivation layer 181 are patterned to define the opening 81 overlapping the pad PD and the opening 82 overlapping the drain electrode DE. A center portion of the second auxiliary layer P2, which is the uppermost layer of the pad PD, is exposed by the opening 81, and an edge of the second auxiliary layer P2 is covered by the passivation layer 181. Then, the portion exposed through the opening 81 in the second auxiliary layer P2 of the pad PD is etched. In this step, a portion of the second auxiliary layer of the drain electrode DE exposed through the opening 82 may also be etched. An etchant having high selectivity to a material of the first auxiliary layer P1 may be used such that the first auxiliary layer P1 is not etched when the second auxiliary layer P2 is etched. Since the portion of the second auxiliary layer P2 exposed by the opening 81 is etched, the first auxiliary layer P1 of the pad PD is exposed in the region overlapping the opening 81. However, since the portion of the second auxiliary layer P2 that is not exposed by the opening 81 is not etched, the portion of the second auxiliary layer P2 overlapping the passivation layer 181 remains between the first auxiliary layer P1 and the passivation layer 181.

An etchant having high selectivity to a material of the first auxiliary layer P1 which is an exposed layer of the pad PD may be used such that the pad PD is not damaged when the conductive layer for forming the first electrode E1 is etched. For example, in a case that the main layer P0 of the pad PD is formed of copper (Cu) and the first electrode E1 is formed of an ITO, the main layer P0 may be eroded by the etchant used during patterning for forming the first electrode E1 if the first auxiliary layer P1 does not cover the main layer P0. However, in an embodiment, since the first auxiliary layer P1 formed of a metal having excellent corrosion resistance to the etchant of ITO, such as titanium (Ti), covers the main layer P0, it is possible to prevent the pad PD from being damaged. In addition, since the first auxiliary layer P1 is formed together in the process of forming the main layer P0, it is not necessary to add a mask in forming an auxiliary layer for protecting the main layer P0 from an etchant used in a subsequent process.

Regarding the subsequent process, referring to FIG. 9, a conductive layer is formed and patterned on the insulating layer 182 to form the first electrode E1 of the light emitting diode LED. The first electrode E1 is connected to the drain electrode DE through the opening 82 defined in the insulating layer 182. Since a portion overlapping the opening 82 is eliminated from the second auxiliary layer of the drain electrode DE, the drain electrode DE may contact an upper surface of the first auxiliary layer.

Next, the partition wall 360, the light emitting layer EL, and the second electrode E2 are formed on the substrate 110 (more specifically, on the insulating layer 182) on which the first electrode E1 is formed, thereby manufacturing the display panel 10 having the cross-sectional structure as illustrated in FIG. 9.

In an embodiment, the portion exposed by the opening 81 in the second auxiliary layer P2 of the pad PD may be eliminated during patterning for forming the first electrode E1. Since the pad PD is exposed due to the opening 81 during patterning for forming the first electrode E1, the second auxiliary layer P2 may be etched together by using an etchant that can etch both the second auxiliary layer P2 and the first electrode E1. In this case, the portion of the second auxiliary layer of the drain electrode DE that overlaps the opening 82 is not eliminated and completely covers the first auxiliary layer. As another example, the second auxiliary layer P2 may be entirely eliminated after forming the data conductor and before forming the passivation layer 181.

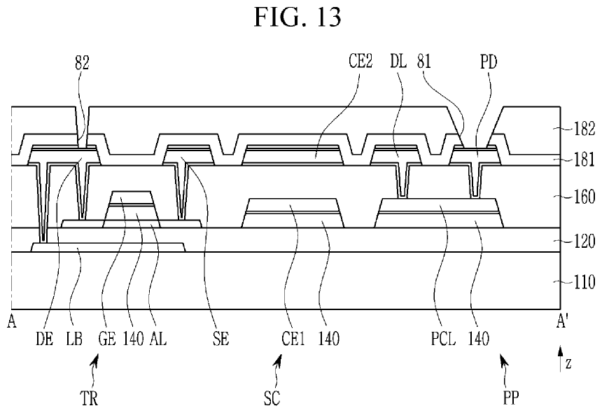

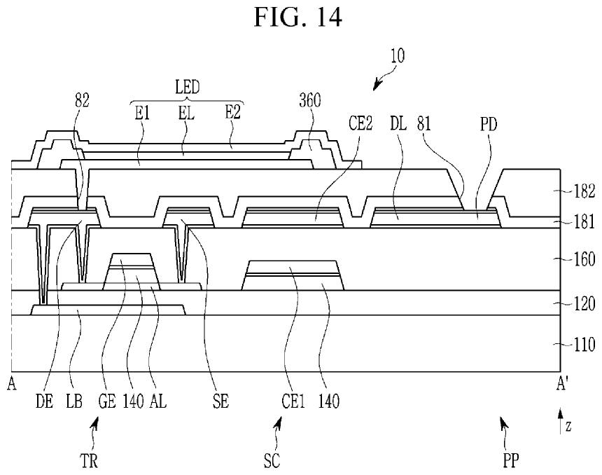

FIG. 14 illustrates a schematic cross-sectional view of a display device according to an embodiment.

The embodiment of FIG. 14 differs from the embodiment of FIG. 9 in the connection of the data line DL and the pad PD. In the embodiment of FIG. 9, the data line DL and the pad PD are electrically connected through the pad connecting line PCL, but the display panel 10 of the embodiment of FIG. 14 does not include the pad connecting line PCL. Instead, the data line DL extends to the pad PD, and the data line DL and the pad PD are integrally formed (i.e., monolithic). The pad PD may be regarded as an extension portion or an expansion portion of the data line DL.

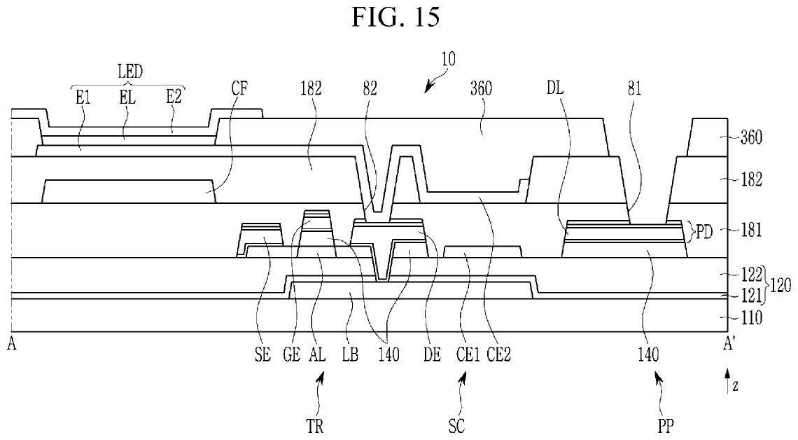

FIG. 15 illustrates a schematic cross-sectional view of a display device according to an embodiment.

FIG. 15 illustrates a cross-sectional structure of the display panel 10 in which the source electrode SE and the drain electrode DE of the transistor TR, the pad PD, and the like are disposed in the same layer with the gate electrode GE of the transistor TR.

Referring to FIG. 15, the light blocking layer LB is disposed on the substrate 110, and the buffer layer 120 is disposed on the light blocking layer LB. The buffer layer 120 may be a double layer including a lower layer 121 and an upper layer 122.

The semiconductor layer AL of the transistor TR and the first electrode CE1 of the storage capacitor SC may be disposed on the buffer layer 120. The first electrode CE1 may be disposed in the same layer with the semiconductor layer AL. Like the source region and the drain region of the semiconductor layer AL, the first electrode CE1 is formed and doped with a semiconductor material such as an oxide semiconductor, polycrystalline silicon, or amorphous silicon. The first electrode CE1 may be connected to the gate electrode GE of the transistor TR.

The gate insulating layer 140 may be disposed on the buffer layer 120 and the semiconductor layer AL.

The gate conductor including the gate electrode GE, the source electrode SE, and the drain electrode DE of the transistor TR, the data line DL, and the pad PD may be disposed on the buffer layer 120, the semiconductor layer AL, and the gate insulating layer 140. The gate electrode GE, the source electrode SE, the drain electrode DE, the data line DL, and the pad PD may be formed of the same material in the same process. By forming the source electrode SE and the drain electrode DE together with the gate electrode GE, the number of processes and masks for forming the source electrode SE and the drain electrode DE may be reduced. In an embodiment, a power line such as a driving voltage line, a common voltage line, and an initializing voltage line may also be a gate conductor formed of the same material in the same process as the gate electrode GE.

Similar to the data conductor of the embodiment of FIG. 9, the gate conductor may be a multilayer including at least three layers. The multilayer may be formed by successively stacking layers while the layers have varying materials. The data conductor may include a main layer including a low resistivity metal, a first auxiliary layer, and a second auxiliary layer sequentially disposed at an upper portion of the main layer. The gate conductor may further include a third auxiliary layer disposed at a lower portion of the main layer. Such a gate conductor may be formed by successively stacking four layers and then patterning the layers at once.

For example, the gate conductor may be formed by successively stacking and patterning a first layer including a metal such as titanium (Ti), molybdenum (Mo), and the like; a second layer including a metal having low resistivity such as copper (Cu), aluminum (Al), and silver (Ag); a third layer including a corrosion resistant material such as titanium (Ti), molybdenum (Mo), and tungsten (W); and a fourth layer including a conductive oxide such as a zinc indium oxide (ZIO), a gallium zinc oxide (GZO), and an aluminum zinc oxide (AZO). In an embodiment, the second layer may correspond to the main layer, the third layer and the fourth layer may correspond to the first auxiliary layer and the second auxiliary layer, respectively, and the first layer may correspond to the third auxiliary layer.

Since the second auxiliary layer is continuously formed on the first auxiliary layer and then patterned to form the gate conductor together, the formation of the oxide film in the first auxiliary layer may be suppressed, and even if the oxide film is formed on the first auxiliary layer, its thickness and dispersion may be reduced. Therefore, it is easy to control the etching process for forming the gate conductor, and the structural uniformity of the gate conductor (particularly, the pad PD) may be improved.

The gate insulating layer 140 may not exist between the source electrode SE and the source region of the semiconductor layer AL, and, therefore, the source electrode SE may directly contact the source region. Similarly, the gate insulating layer 140 may not exist between the drain electrode DE and the drain region of the semiconductor layer AL, and, therefore, the drain electrode DE may directly contact the drain region. The drain electrode DE may be connected to the light blocking layer LB through the opening defined in the buffer layer 120.

The passivation layer 181 may be disposed on the gate conductor. The passivation layer 181 defines the opening 81 overlapping the pad PD and the opening 82 overlapping the drain electrode DE such that the pad PD may be exposed to the outside for connection with a pad and the like of the flexible printed circuit film. The opening 81 is defined such that the pad PD is not completely exposed, and the passivation layer 181 covers an edge of the pad PD. The entire portion of the second auxiliary layer, which is the uppermost layer of the pad PD, may overlap the passivation layer 181. The edge of the second auxiliary layer may substantially coincide with the edge of the first auxiliary layer. The passivation layer 181 may include an inorganic insulating material and may include an organic insulating material.

A color filter CF may be disposed on the passivation layer 181. The color filter CF may display one of three primary colors, for example, red, green, and blue. In the illustrated structure, the light emitted from the light emitting diode LED may pass through the color filter CF and be emitted to a rear surface of the display device through the substrate 110. Since the three primary colors may be displayed by the color filter CF, the light emitting diode LED may emit white light and/or blue light.

The insulating layer 182 may be disposed on the passivation layer 181 and the color filter CF. The first electrode E1 of the light emitting diode LED and the second electrode CE2 of the storage capacitor SC may be disposed on the insulating layer 182. The first electrode E1 and the second electrode CE2 may be formed of the same material in the same process.

The first electrode E1 may be connected to the drain electrode DE through the opening 82 defined in the insulating layer 182 and the passivation layer 181. The second electrode CE2 may also be connected to the drain electrode DE through the opening 82. The second electrode CE2 may form the storage capacitor SC together with the overlapping first electrode CE1.

The portion of the second auxiliary layer overlapping the opening 81 may be eliminated by using an etchant or during patterning for forming the first electrode E1, after forming the opening 81 defined in the insulating layer 182 and the passivation layer 181. In the former case (i.e., using an etchant), as shown in the drawing, the portion overlapping the opening 82 in the second auxiliary layer of the drain electrode DE may be eliminated together. In the latter case, the portion of the second auxiliary layer of the drain electrode DE that overlaps the opening 82 is not eliminated and completely covers the first auxiliary layer of the drain electrode DE. As another example, the second auxiliary layer may be entirely eliminated after forming the gate conductor and before forming the passivation layer 181.

The partition wall 360 may be disposed on the first electrode E1 of the light emitting diode LED and the second electrode CE2 of the storage capacitor SC. The light emitting layer EL may be disposed on the first electrode E1, and the second electrode E2 may be disposed on the light emitting layer EL. The first electrode E1, the light emitting layer EL, and the second electrode E2 may form the light emitting diode LED.

The partition wall 360 may define an opening overlapping the pad PD or may be eliminated from the pad part PP. In the display panel 10, the pad PD is exposed, and a signal inputted to the pad PD may be transmitted to a signal line such as a data line.

Finally, the pixel PX of the display device will be described in terms of a pixel circuit.

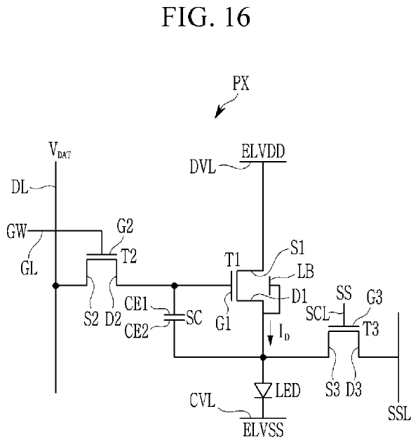

FIG. 16 illustrates an equivalent circuit diagram of one pixel of a display according to an embodiment.

Referring to FIG. 16, the pixel PX includes transistors T1, T2, and T3, a storage capacitor SC, and a light emitting diode LED. Signal lines DL, GL, SCL, SSL, DVL, and CVL are connected to the pixel PX. Although it is illustrated that the pixel PX has a structure including three transistors and one capacitor, the number and connection of the transistors and the capacitor may be variously changed. Although a structure in which six signal lines are connected to the pixel PX is illustrated, the type and number of signal lines may be variously changed.

The signal lines DL, GL, SCL, SSL, DVL, and CVL may include a data line DL, a gate line GL, a sensing control line SCL, a sensing line SSL, a driving voltage line DVL, and a common voltage line CVL. The gate line GL may transmit a gate signal GW to the second transistor T2. The data line DL may transmit a data voltage V_{DAT}, the driving voltage line DVL may transmit a driving voltage ELVDD, and the common voltage line CVL may transmit a common voltage ELVSS. The sensing control line SCL may transmit a sensing signal SS, and the sensing line SSL may be connected to a sensing portion.

The transistors T1, T2, and T3 include a first transistor T1 which is a driving transistor, a second transistor T2 which is a switching transistor, and a third transistor T3 which is a sensing transistor. The transistors T1, T2, and T3 are three-terminal elements including gate electrodes G1, G2, and G3, source electrodes S1, S2, and S3, and drain electrodes D1, D2, and D3, respectively. The positions of the source electrode and the drain electrode are variable, and one of two terminals except the gate electrode of three terminals of the transistor may be a source electrode, and the other thereof may be a drain electrode.

In an embodiment, the gate electrode G1 of the first transistor T1 is connected to the first electrode CE1 of the storage capacitor SC and the drain electrode D2 of the second transistor T2, the source electrode S1 of the first transistor T1 is connected to the driving voltage line DVL, and the drain electrode D1 of the first transistor T1 is connected to the anode of the light emitting diode LED. The first transistor T1 may supply a driving current I_{D} that varies according to a data voltage V_{DAT} transmitted through the second transistor T2 to the light emitting diode LED, and the light emitting diode LED may emit light with a varying luminance according to the driving current I_{D}. Accordingly, the pixel PX may display a gray level by adjusting an amount of a current flowing through the first transistor T1 according to the data voltage V_{DAT}. The driving current I_{D} may be depending on a gate-source voltage which is a voltage between the gate electrode G1 and the source electrode S1 of the first transistor T1. That is, as the voltage of the first transistor T1 increases, the driving current I_{D} may increase. The light blocking layer LB, which may overlap the semiconductor layer of the first transistor T1, is connected to the drain electrode D1 of the first transistor T1, thus characteristics of the first transistor T1, such as an output saturation characteristic, may be improved.

In an embodiment, the gate electrode G2 of the second transistor T2 is connected to the gate line GL, the source electrode S2 of the second transistor T2 is connected to the data line DL, and the drain electrode D2 of the second transistor T2 is connected to the gate electrode G1 of the first transistor T1 and the first electrode CE1 of the storage capacitor SC. The second transistor T2 may perform a switching operation in which it is turned on according to the gate signal GW received through the gate line GL and transmit the data voltage V_{DAT} transmitted through the data line DL to the gate electrode G1 of the first transistor T1 and the first electrode CE1 of the storage capacitor SC.

In an embodiment, the gate electrode G3 of the third transistor T3 is connected to the sensing control line SCL, the source electrode S3 of the third transistor T3 is connected to the drain electrode D1 of the first transistor T1 and the anode of the light emitting diode LED, and the drain electrode D3 of the third transistor T3 is connected to the sensing line SSL. The third transistor T3 is a transistor for sensing a characteristic such as a threshold voltage of the first transistor T1 that causes deterioration of image quality. The third transistor T3 is turned on according to the sensing signal SS received through the sensing control line SCL to electrically connect the first transistor T1 and the sensing line SSL, and the sensing portion connected to the sensing line SSL may sense characteristic information of the first transistor T1 during a sensing period. By generating a data voltage that is compensated by reflecting the characteristic information sensed by the third transistor T3 during the sensing period, it is possible to externally compensate for characteristic variations of the first transistor T1 that may be different for respective pixels PX. An initializing voltage is applied to the anode of the light emitting diode LED through the sensing line SSL to be able to initialize a voltage of the anode to the initializing voltage.

In an embodiment, the first electrode CE1 of the storage capacitor SC is connected to the gate electrode G1 of the first transistor T1 and the drain electrode D2 of the second transistor T2, and the second electrode CE2 of the storage capacitor SC is connected to the drain electrode D1 of the first transistor T1, the source electrode S3 of the third transistor T3, and the anode of the light emitting diode LED. The storage capacitor SC may continuously apply the charged data voltage V_{DAT} to the first transistor T1 to continuously emit the light emitting diode LED during a light emitting period. The cathode of the light emitting diode LED may be connected to the common voltage line CVL which transmits the common voltage ELVSS.

While the inventive concept has been described in connection with what is presently considered to be embodiments, it is to be understood that the inventive concept is not limited to the disclosed embodiments, but, on the contrary, is intended to cover various modifications and equivalent arrangements included within the spirit and scope of the appended claims.

What is claimed is:

1. A display device comprising:
a substrate which includes a display area and a non-display area;
a transistor disposed in the display area;
a pad disposed in the non-display area; and
an insulating layer which is disposed on the transistor and defines an opening which overlaps the pad in a plan view,
wherein the pad includes a main layer, a first auxiliary layer on the main layer, and a second auxiliary layer on the first auxiliary layer, and the second auxiliary layer defines the opening.

2. The display device of claim 1, wherein
the insulating layer covers an edge of the pad, and
the second auxiliary layer is disposed between the first auxiliary layer and the insulating layer.

3. The display device of claim 2, wherein
an edge of the second auxiliary layer and an edge of the first auxiliary layer substantially coincide with each other.

4. The display device of claim 1, wherein
the second auxiliary layer includes a conductive oxide.

5. The display device of claim 4, wherein
the conductive oxide includes at least one of a zinc indium oxide, a gallium zinc oxide, and an aluminum zinc oxide.

6. The display device of claim 5, wherein
the main layer includes copper, and the first auxiliary layer includes titanium.

7. The display device of claim 1, wherein
the pad further includes a third auxiliary layer under the main layer.

8. The display device of claim 1, wherein
the pad is connected to a signal line disposed in the display area.

9. The display device of claim 8, further comprising
a pad connecting electrode which overlaps the pad,
wherein the pad is connected to the signal line through the pad connecting electrode.

10. The display device of claim 9, wherein
the signal line is a data line which transmits a data voltage, and the pad connecting electrode is disposed in a same layer with the data line.

11. The display device of claim 8, further comprising
a connecting member disposed on a source or drain electrode of the transistor and connected to the source or drain electrode,
wherein the pad is disposed in a same layer with the connecting member.

12. The display device of claim 8, wherein
the signal line is a data line which transmits a data voltage, and the pad is disposed in a same layer with the data line.

13. The display device of claim 12, wherein
the pad and the data line are monolithic.

14. The display device of claim 8, wherein
the pad is disposed in a same layer with the gate electrode of the transistor.

15. A display device comprising:
a substrate;
a pad disposed on the substrate; and
a first insulating layer which is disposed on the pad and defines an opening which overlaps a portion of the pad,
wherein the pad includes a main layer, a first auxiliary layer on the main layer, and a second auxiliary layer on the first auxiliary layer, and
the first auxiliary layer is exposed in an area in which the second auxiliary layer defines the opening.

16. The display device of claim 15, wherein
the first insulating layer covers an edge of the pad, and
the second auxiliary layer is disposed between the first auxiliary layer and the first insulating layer.

17. The display device of claim 15, wherein
edges of the main layer, the first auxiliary layer, and the second auxiliary layer substantially coincide with each other.

18. The display device of claim 15, wherein
the main layer includes copper, the first auxiliary layer includes at least one of titanium, molybdenum, and tungsten, and the second auxiliary layer includes at least one of a zinc indium oxide, a gallium zinc oxide, and an aluminum zinc oxide.

19. The display device of claim 15, further comprising
a second insulating layer which is disposed on the first insulating layer and defines the opening,
wherein the first insulating layer includes an inorganic insulating material, and the second insulating layer includes an organic insulating material.

20. The display device of claim 15, further comprising
a data line which is connected to the pad and transmits a data voltage,
wherein the pad is disposed in a same layer with the data line.
